(19) United States
(12) Patent Application Publication
(10) Pub. No.: US 2024/0202812 A1
(43) Pub. Date: Jun. 20, 2024

(54) SYSTEM AND METHOD FOR VIRTUAL DESIGNING

(71) Applicant: Vito Rullo, Langrangeville, NY (US)

(72) Inventor: Vito Rullo, Langrangeville, NY (US)

(21) Appl. No.: 18/512,163

(22) Filed: Nov. 17, 2023

Related U.S. Application Data
(60) Provisional application No. 63/432,922, filed on Dec. 15, 2022.

(51) Int. Cl. G06Q 30/0601; G06F 30/13

(52) U.S. Cl. CPC G06Q 30/0643; G06F 30/13; G06Q 30/0621

(57) ABSTRACT

A system and method for virtual designing is provided. The system is configured to allow users to virtually edit the image with different colors, designs, and other parameters. The mobile device may communicate wirelessly with a database that is accessible by contractors and other similar professionals. The contractors may then contact the individual with an estimate based on the customized image they upload to the database. In this way, the system allows individuals to develop and view potential designs without the need for a professional engineer or designer services, and further allows individuals to receive a cost estimate to achieve their custom design.

### CROSS REFERENCE TO RELATED APPLICATIONS

This application claims the benefit of U.S. Provisional Application No. 63/432,922 filed on Dec. 15, 2022. The above identified patent application is herein incorporated by reference in its entirety to provide continuity of disclosure.

### BACKGROUND OF THE INVENTION

The present invention relates to a system and method for designing. More specifically, the invention relates to a system and method for virtual designing.

Many individuals wish to improve their home, however home improvement estimates may be difficult to schedule and are often expensive. Planning potential improvements similarly often requires an expert assessment and plan to fully realize a desired new design. Typically, an individual must contact one or more designers or construction experts to visit the home, take measurements, draft the proposed improvements, and ultimately estimate how much the updates will cost. Individuals may seek multiple estimates and designs from various designers and companies, the costs and scheduling restrictions of which may represent a significant investment of time and money.

In order to address these concerns, the present invention will provide users with a system and method for virtual designing that allows a user to modify a photo of an area with various new designs, objects, colors, and patterns, which may then automatically be sent to various designers to provide estimates within a desired timeframe. In this manner, the system and method for virtual designing will reduce the cost and improve the efficiency of planning home improvement designs.

### SUMMARY OF THE INVENTION

In view of the foregoing disadvantages inherent in the known types of systems and methods for virtual designing now present in the prior art, the present invention provides a system and method for virtual designing wherein the same may be utilized for providing convenience for a user when using a system and method for virtual designing.

The present system comprises a system for virtual designing that includes a server system with a processor system, a communications interface, a communications system, an input system and an output system, the server system having access to a communications network, a memory system with an operating system, a communications module, a web browser module, a web server application, and a non-transitory storage media for virtual designing, the memory system is in communication with the server system through the communications network, and a plurality of mobile screenshots residing on the non-transitory storage media for virtual designing, and wherein the mobile screenshots are taken with a camera from a client system to record an image of space that saved as one of the mobile screenshots residing on the non-transitory storage media for virtual designing.

The present system also includes a corresponding method for virtual designing comprising the steps of obtaining a client system having a camera and a display screen, taking the camera of the client system to record an image of space, virtually editing the image of space with a plurality of different colors and a plurality of different designs, applying over the image of space a plurality of modifiers, a plurality of patterns, a plurality of virtual objects, a plurality of colors, and a plurality of designs, and dragging and dropping the desired changes over the image of space to visualize a plurality of proposed improvements.

The present system also includes a corresponding non-transitory computer storage media having instructions stored thereon which, when executed, execute a method comprising the steps obtaining a client system having a camera and a display screen, taking the camera of the client system to record an image of space, virtually editing the image of space with a plurality of different colors and a plurality of different designs, applying over the image of space a plurality of modifiers, a plurality of patterns, a plurality of virtual objects, a plurality of colors, and a plurality of designs, and dragging and dropping the desired changes over the image of space to visualize a plurality of proposed improvements.

### BRIEF DESCRIPTION OF THE DRAWINGS

Although the characteristic features of this invention will be particularly pointed out in the claims, the invention itself and manner in which it may be made and used may be better understood after a review of the following description, taken in connection with the accompanying drawings wherein like numeral annotations are provided throughout.

FIG. 1 shows a system overview of a system for virtual designing.

FIG. 2A shows a block diagram of a client system of a system for virtual designing.

FIG. 2B illustrates a block diagram of a server system of a system for virtual designing.

FIG. 3 shows a cover mobile screenshot of a system for virtual designing.

FIG. 4 shows a log-in mobile screenshot of a system for virtual designing.

FIG. 5 shows a create an account mobile screenshot of a system for virtual designing.

FIG. 6 shows a client information mobile screenshot of a system for virtual designing.

FIG. 7 shows a search for contractor mobile screenshot of a system for virtual designing.

FIG. 8 shows a contractor information mobile screenshot of a system for virtual designing.

FIG. 9 shows a photo of a project mobile screenshot of a system for virtual designing.

FIG. 10 shows an estimate mobile screenshot of a system for virtual designing.

FIG. 11 shows a detailed estimate mobile screenshot of a system for virtual designing.

FIG. 12 shows a user communications mobile screenshot of a system for virtual designing.

FIG. 13 shows a contractor communications mobile screenshot of a system for virtual designing.

FIG. 14 shows a payment information mobile screenshot of a system for virtual designing.

FIG. 15 shows a payment confirmation information mobile screenshot of a system for virtual designing.

### DETAILED DESCRIPTION OF THE INVENTION

Reference is made herein to the attached drawings. Like reference numerals are used throughout the drawings to depict like or similar elements of a system and method for virtual designing. The figures are intended for representative purposes only and should not be considered to be limiting in any respect.

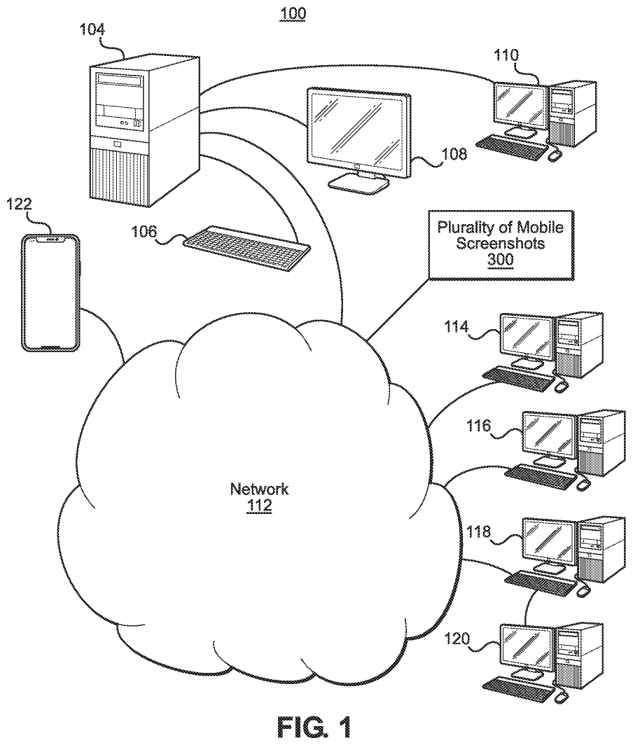

Referring now to FIG. 1 there is shown a system overview of a system and method for virtual designing 100.

The overall system 100 includes a server system 104, an input system 106, an output system 108, a plurality of client systems 110, 114, 116, 118 and 120, a communications network 112, a hand-held device 122 and a plurality of mobile screenshots 300. In other embodiments, the overall system 100 may include additional components and/or may not include all of the components listed above.

The server system 104 may include one or more servers. One server 104 may be the property of the distributor of any related software or non-transitory storage media. In other embodiments, the overall system 100 may include additional components and/or may not include all of the components listed above.

The input system 106 may be used for entering input into the server system 104, and may include any one of, some of, any combination of, or all of a keyboard system, a mouse system, a track ball system, a track pad system, a plurality of buttons on a handheld system, a scanner system, a wireless receiver, a microphone system, a connection to a sound system, and/or a connection and/or an interface system to a computer system, an intranet, and/or the Internet (i.e., IrDA, USB), for example.

The output system 108 may be used for receiving output from the server system 104, and may include any one of, some of, any combination of or all of a monitor system, a wireless transmitter, a handheld display system, a printer system, a speaker system, a connection or an interface system to a sound system, an interface system to one or more peripheral devices and/or a connection and/or an interface system to a computer system, an intranet, and/or the Internet, for example.

The overall system 100 illustrates some of the variations of the manners of connecting to the server system 104, which may be an information providing website (not shown). The server system 104 may be directly connected and/or wirelessly connected to the client systems 110, 114, 116, 118 and 120 and are connected via the communications network 112. Client systems 120 may be connected to the server system 104 via the client system 118. The communications network 112 may be any one of, or any combination of, one or more local area networks or LANs, wide area networks or WANs, wireless networks, telephone networks, the Internet and/or other networks. The communications network 112 may include one or more wireless portals (not shown). The client systems 110, 114, 116, 118 and 120 are any system that an end user may use to access the server system 104. For example, the client systems 110, 114, 116, 118 and 120 may be personal computers, workstations, laptop computers, game consoles, handheld network enabled audio/video players and/or any other network appliance.

The client system 120 accesses the server system 104 via the combination of the communications network 112 and another system, which in this example is the client system 118.

The client system 120 is an example of a handheld wireless device 122, such as a mobile phone or a handheld network enabled audio/music player or the like, which may also be used for accessing network content.

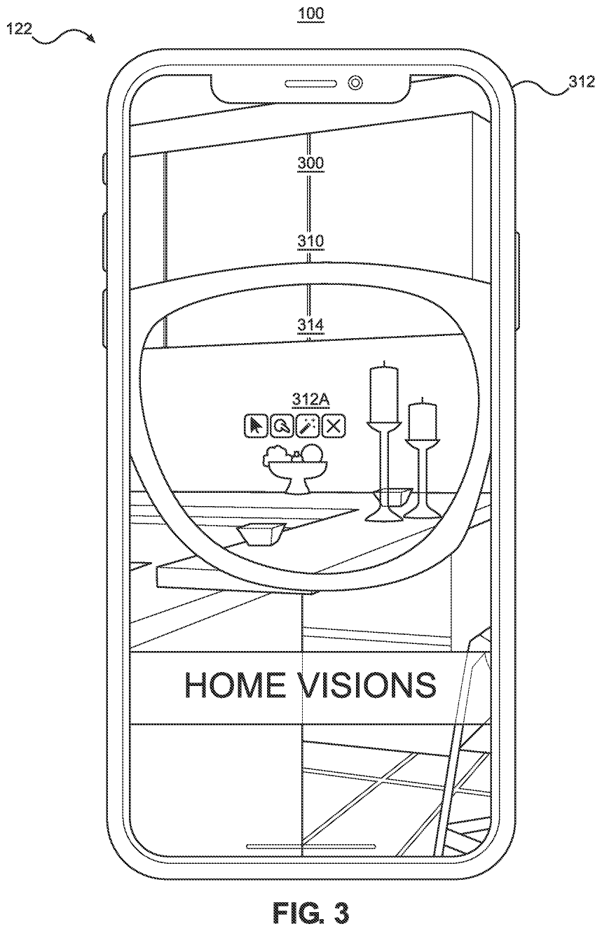

The mobile screenshots 300 is described in more detail in FIGS. 3-15.

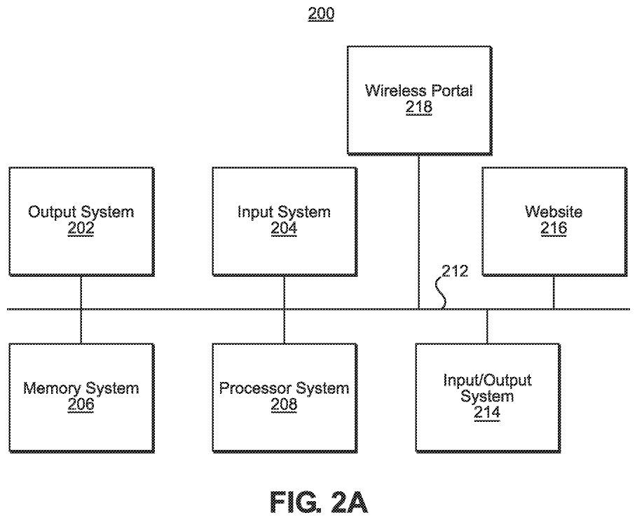

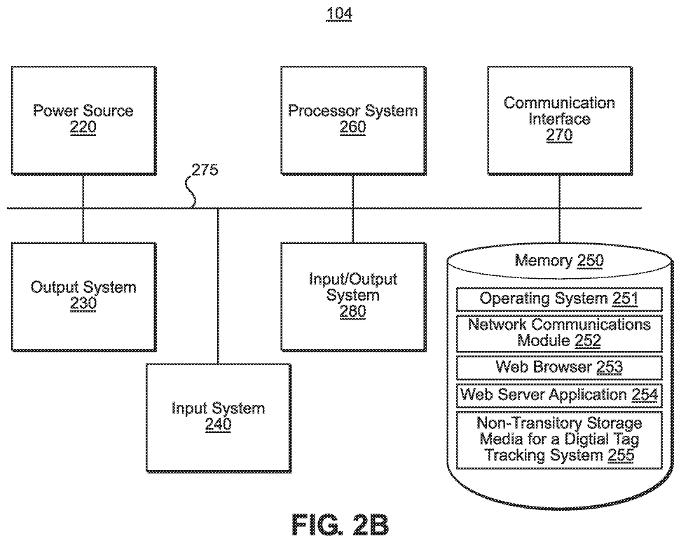

Referring now to FIG. 2A there is shown a block diagram of a client system 200 of the system for virtual designing 100.

The client system 200 may include an output system 202, an input system 204, a memory system 206, a processor system 208, a communications system 212, an input/output system 214, a website 216 and a wireless portal 218. Other embodiments of the client system 200 may not have all of the components and/or may have other embodiments in addition to or instead of the components listed above.

The client system 200 may be any one of the client systems 110, 114, 116, 118, 120, and/or cellphone 122 that may be used as one of the network devices of FIG. 1. In other embodiments, the client system 200 may include additional components and/or may not include all of the components listed above. The output system 202 may include any one of, some of, any combination of or all of a monitor system, a wireless transmitter, a handheld display system, a printer system, a speaker system, a connection or an interface system to a sound system, an interface system to peripheral devices and/or a connection and/or an interface system to a computer system, an intranet, and/or the Internet, for example.

The input system 204 may include any one of, some of, any combination of, or all of a keyboard system, a mouse system, a track ball system, a track pad system, one or more buttons on a handheld system, a scanner system, a wireless receiver, a microphone system, a connection to a sound system, and/or a connection and/or an interface system to a computer system, an intranet, and/or the Internet (i.e., Infrared Data Association or IrDA, Universal Serial Bus or USB), for example. The memory system 206 may include, for example, any one of, some of, any combination of or all of a long-term storage system, such as a hard drive, a short-term storage system, such as a random-access memory; a removable storage system, such as a floppy drive or a removable drive, and/or a flash memory. The memory system 206 may include one or more machine-readable mediums that may store a variety of different types of information. The term machine-readable medium is used to refer to any medium that is structurally configured for carrying information in a format that is readable by a machine. One example of a machine-readable medium is a computer-readable medium. The memory system 206 also stores a non-transitory storage media for system and method for virtual designing.

The processor system 208 may include any one of, some of, any combination of, or all of multiple parallel processors, a single processor, a system of processors having one or more central processors and/or one or more specialized processors dedicated to specific tasks. The processor system 208 implements the programs stored in the memory system 206. The communications system 212 communicatively buttons the output system 202, the input system 204, the memory system 206, the processor system 208, and/or the input/output system 214 to each other. The communications system 212 may include any one of, some of, any combination of, or all of one or more electrical cables, fiber optic cables, and/or means for sending signals through air or water (i.e., wireless communications), or the like. Some examples of means for sending signals through air and/or water include systems for transmitting electromagnetic waves such as infrared and/or radio waves and/or systems for sending sound waves.

The input/output system 214 may include devices that have the dual function as input and output devices. For example, the input/output system 214 may include one or more touch sensitive screens, which display an image and therefore are an output device and accept input when the screens are pressed by a finger or a stylus, for example. The touch sensitive screens may be sensitive to heat, capacitance and/or pressure. One or more of the input/output devices may be sensitive to a voltage or a current produced by a stylus, for example. The input/output system 214 is optional and may be used in addition to or in place of the output system 202 and/or the input device 204.

The client systems 110, 114, 116, 118, 120 and the handheld wireless device 122 may also be tied into a website 216 or a wireless portal 218 which is also tied directly into the communications system 212. Any website 216 or wireless portal 218 would also include software and a website module (no number) to maintain, allow access to and run the website as well.

FIG. 2B shows a block diagram of a server system 104 of the system for using a system and method for virtual designing 100.

The server system 104 may include a power source 220, an output system 230, an input system 240, a memory system 250, which may store an operating system 251, a communications module 252, a web browser module 253, a web server application 254, and a non-transitory storage media for virtual designing 255. The server system 104 may also include a processor system 260, a communications interface 270, a communications system 275 and an input/output system 280. In other embodiments, the server system 104 may include additional components and/or may not include all of the components listed above.

The output system 230 may include any one of, some of, any combination of, or all of a monitor system, a handheld display system, a printer system, a speaker system, a connection or interface system to a sound system, an interface system to one or more peripheral devices and/or a connection and/or interface system to a computer system, an intranet, and/or the Internet, for example.

The input system 240 may include any one of, some of, any combination of, or all of a keyboard system, a mouse system, a track ball system, a track pad system, one or more buttons on a handheld system, a scanner system, a microphone system, a connection to a sound system, and/or a connection and/or an interface system to a computer system, an intranet, and/or the Internet (i.e., IrDA, USB), for example.

The memory system 250 may include, for example, any one of, some of, any combination of, or all of a long-term storage system, such as a hard drive; a short-term storage system, such as random-access memory; a removable storage system, such as a floppy drive or a removable drive and/or a flash memory. The memory system 250 may include one or more machine-readable mediums that may store a variety of different types of information. The term machine-readable medium is used to refer to any medium capable of carrying information that is readable by a machine. One example of a machine-readable medium is a computer-readable medium. The memory system 250 may store one or more machine instructions for reading, searching and enhancing a system and method for virtual designing. The operating system 251 controls all software or non-transitory storage media and hardware of the overall system 100. The communications module 252 may enable the server system 104 to communicate on the communications network 112. The web browser module 253 allows for browsing the Internet. The web server application 254 serves a plurality of web pages to client systems that request the webpages, thereby facilitating browsing on the Internet.

The processor system 260 may include any one of, some of, any combination of, or all of multiple parallel processors, a single processor, a system of processors having one or more central processors and/or one or more specialized processors dedicated to specific tasks. The processor system 260 may implement the machine instructions stored in the memory system 250.

In an alternative embodiment, the communication interface 270 allows the server system 104 to interface with the network 112. In this embodiment, the output system 230 sends communications to the communication interface 270. The communications system 275 communicatively buttons the output system 230, the input system 240, the memory system 250, the processor system 260, and/or the input/output system 280 to each other. The communications system 275 may include any one of, some of, any combination of, or all of one or more electrical cables, fiber optic cables, and/or sending signals through air or water (i.e., wireless communications), or the like. Some examples of sending signals through air and/or water include systems for transmitting electromagnetic waves such as infrared and/or radio waves and/or systems for sending sound waves.

The input/output system 280 may include devices that have the dual function as the input and output devices. For example, the input/output system 280 may include one or more touch sensitive screens, which display an image and therefore are an output device and accept input when the screens are pressed by a finger or a stylus, for example. The touch sensitive screens may be sensitive to heat and/or pressure. One or more of the input/output devices may be sensitive to a voltage or a current produced by a stylus, for example. The input/output system 280 is optional and may be used in addition to or in place of the output system 230 and/or the input device 240.

FIG. 3 shows a cover mobile screenshot 310 from one of the mobile screenshots 300 of a system for virtual designing 100.

The cover mobile screenshot 310 may reside on a mobile device (FIG. 1, 122) that may include at least a camera 312 and a display screen 314.

The camera 312 may be configured to record an image of space, such as an interior room of a house, or an exterior area, or the like. The system for virtual designing 100 may be configured to allow users to virtually edit the image of space 312A with different colors, designs, and other parameters. A variety of modifiers, patterns, virtual objects, colors, and designs are available for the user to apply over the image of space 312A taken by the camera 312, such that the user may simply drag and drop the desired changes over the image of space 312A to visualize the proposed improvements. The size, placement, and orientation of the objects may further be altered.

The mobile device 300 may communicate wirelessly with a non-transitory storage media for virtual designing (FIG. 2B, 255) that is accessible by contractors and other similar professionals online. The contractors may then contact the individual with an estimate based on the customized image they upload to the non-transitory storage media for virtual designing (FIG. 2B, 255). Furthermore, in some embodiments, measurements of the area displayed within the image of space 312A may be taken to provide guidance to contractors and users establish more accurate cost estimates. For example, a length, width, and height of a particular flooring design may be displayed within the image, allowing the contractor to more accurately evaluate the amount of work required to install or modify the flooring. In this way, the system for virtual designing 100 allows individuals to develop and view potential designs without the need for a professional engineer or designer services, and further allows individuals to receive a cost estimate to achieve their custom design.

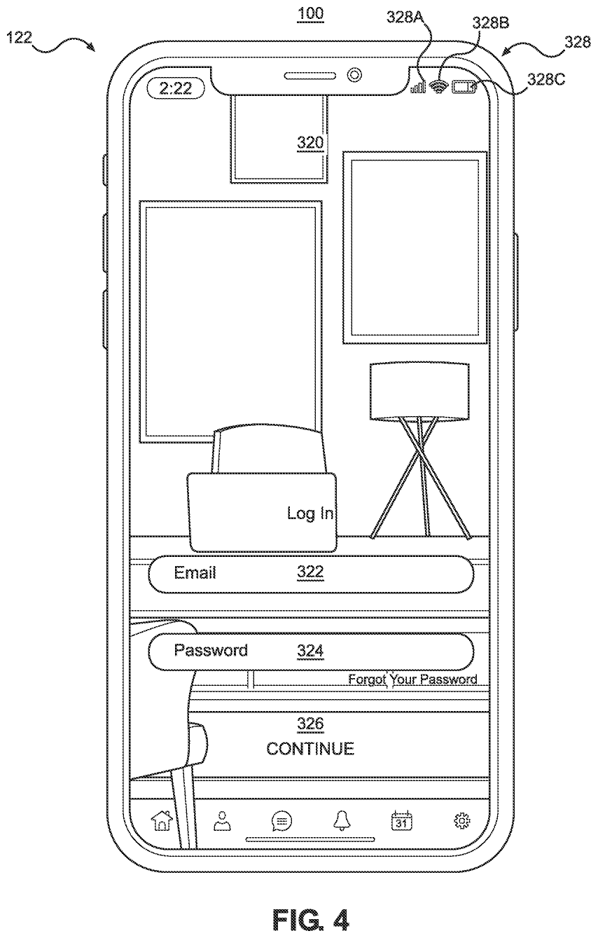

FIG. 4 shows a log-in mobile screenshot 320 of a system for virtual designing 100.

The log-in mobile screenshot 320 may include an email textbox 322, a password textbox 324, a continue button 326, and a plurality of mobile device icons 328.

The email textbox 322 may receive an email address of a user wishing to log-into the system for virtual designing 100. The email address of the user must match the email address of the user in the system for virtual designing 100 for the user to successfully log-in.

The password textbox 324 may include a password of a user wishing to log-into the system for virtual designing 100. The password of the user must match the password of the user in the system for virtual designing 100 for the user to successfully log-in and is chosen and/or created by the user.

The continue button 326 may be depressed after entering the correct email address of the user in the email textbox 322 and the correct password of the user in the password textbox 324.

The mobile device icons 328 may include an Internet signal strength icon 328A, an Internet signal icon 328B, and a battery charge icon 328C.

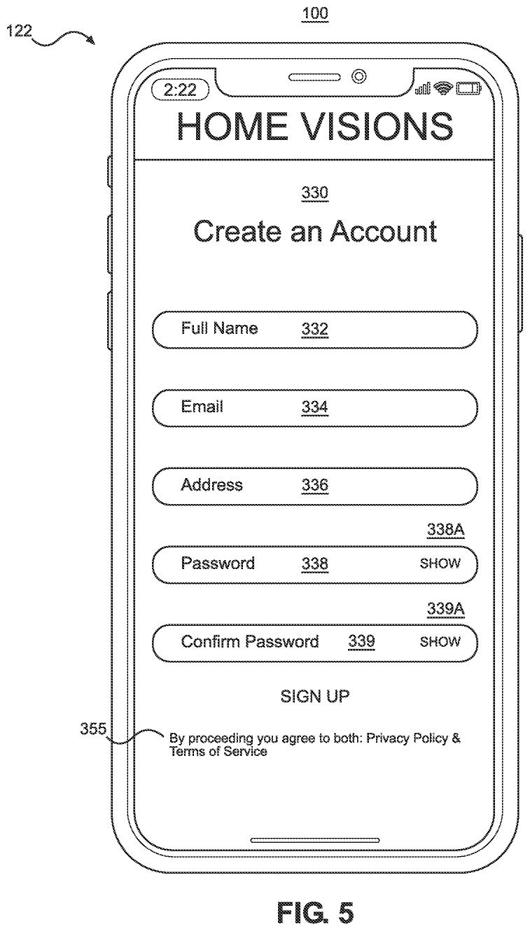

FIG. 5 shows a create an account mobile screenshot 330 of a system for virtual designing 100.

The account mobile screenshot 330 may include a user's full name textbox 332, a user's email textbox 334, an address textbox 336, and a password textbox 338.

The user's full name textbox 332 may include the user's first name, the user's middle name, and the user's last name. The user's email textbox 334 may include the user's email address. The address textbox 336 may include the user's address. The password textbox 338 may include a password created by the user to log into the system for virtual designing 100. The password textbox 338 may include a “Show” link 338A that may be depressed to show the password created by the user to log into the system for virtual designing 100. The password textbox 338 may include a Confirm password textbox 339 that may require the user to reenter the password created by the user to log into the system for virtual designing 100. The Confirm password textbox 339 may include a “Show” link 339A that may be depressed to show the password created by the user to log into the system for virtual designing 100.

The account mobile screenshot 330 may include a Privacy Policy and Terms of Service Statement 335.

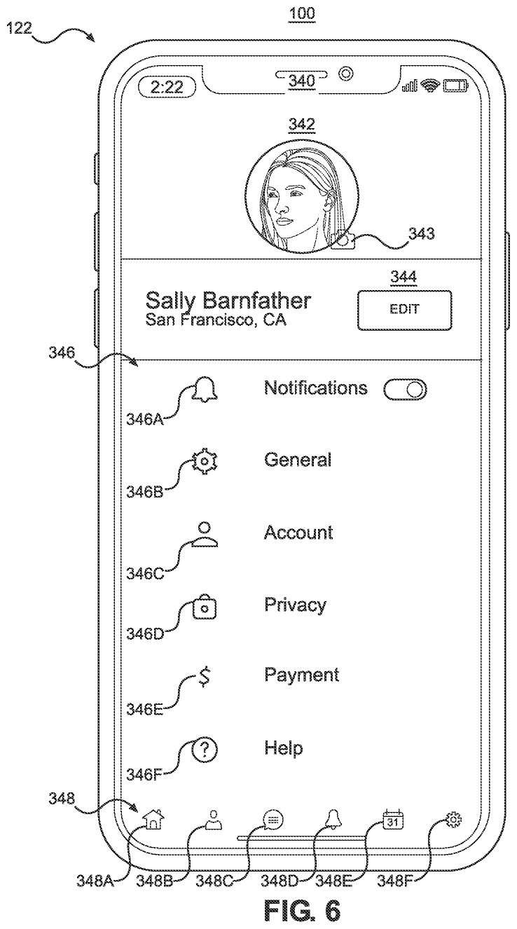

FIG. 6 shows a plurality of client information mobile screenshot 340 of a system for virtual designing 100.

The client information mobile screenshot 340 may include a user's photo 342, an Edit button 344, a plurality of client information types 346, and a plurality of icons 348 disposed on the bottom of the client information mobile screenshot 340.

The user's photo 342 may be a digital photo or the like and include a camera icon 343 that may be depressed to change the user's photo 342. The Edit Button 344 may be depressed to change anything on the client information mobile screenshot 340. The client information types 346 may include a Notifications Toggle Button and Icon 346A, a General information link and icon 346B, an Account Information Link and icon 346C, a Privacy Link and icon 346D, a Payment Link and icon 346E, and a Help Link and icon 346F. The icons 348 disposed on the bottom of the client information mobile screenshot 340 may include a Home Icon 348A, a User Icon 348B, a Text Message Icon 348C, a Notifications Icon 348D, a Calendar Icon 348E, and a Setting Icon 348F.

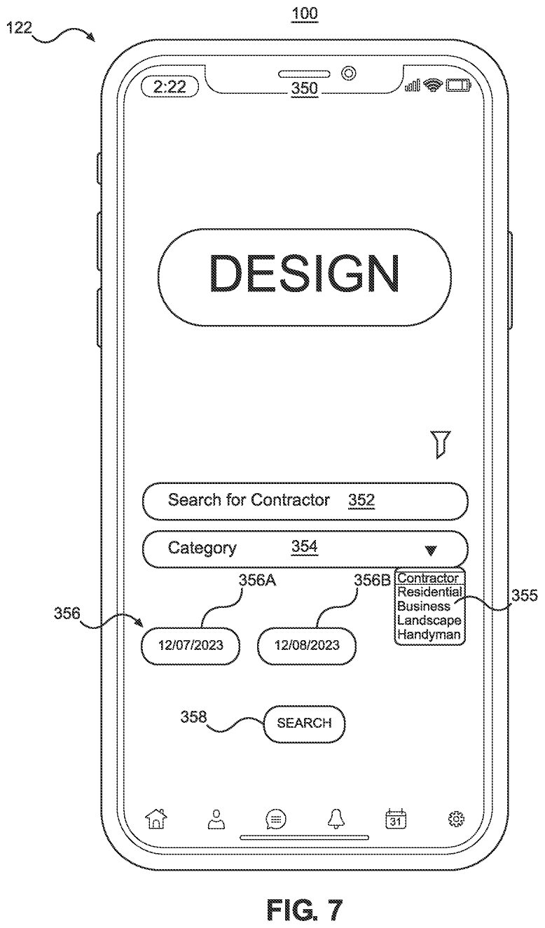

FIG. 7 shows a search for contractor mobile screenshot 350 of a system for virtual designing 100.

The search for contractor mobile screenshot 350 may include a Search For Contractor Textbox 352, a Category Textbox 354, a pair of Data Range Textboxes 356, and a Search Button 358.

The Search for Contractor Textbox 352 may include an entered contactor's name to be searched. The Category Textbox 354 may include a dropdown arrow 355 that include a plurality of Contractor categories such as a Residential Contractor, a Business Contractor, a Landscape Contractor, and a Handyman Contractor or the like. The Pair of Data Range Textboxes 356 may include a Start Date Range 356A and a Finish Date Range 356B. The Search Button 358 may be depressed to generate a plurality of search results after the Search For Contractor Textbox 352, a Category Textbox 354, and a pair of Data Range Textboxes 356 have been completed.

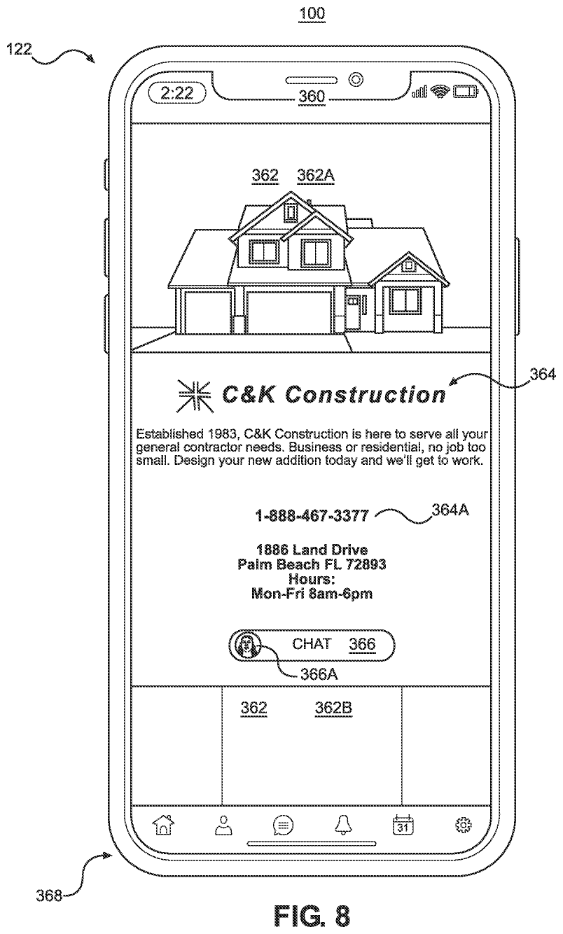

FIG. 8 shows a plurality of contractor information mobile screenshot 360 of a system for virtual designing 100.

The contractor information mobile screenshot 360 may include a Pair of Photos 362, a plurality of Contractor Data 364, a Chat Textbox 366, and a plurality of Icons 368.

The Pair of Photos 362 may include a type of construction photo 362A the contractor does and a Type of Project Photo 362B the contractor does. The Contractor Data 364 may include a Brief Contractor Description 364A that describes the company's history, the type of contractor, a narrative about the contractor, a phone number, an address, and business hours. The Chat Textbox 366 may include a Photo of a Chat Operator 366A and text that is entered in the Chat Textbox 366 and is sent to the Chat Operator 366A. The Icons 368 disposed on the bottom of the client information mobile screenshot 340 are the same icons in FIG. 6, 348. There are also a plurality of Mobile Device Icons 349 that are the same as the Mobile Device Icons 348 in FIG. 6.

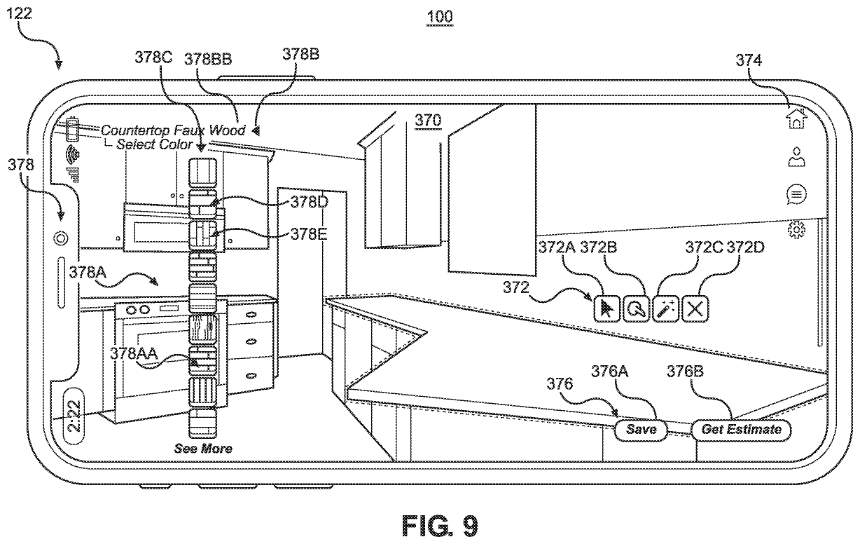

FIG. 9 shows a photo of a project mobile screenshot 370 of a system for virtual designing 100.

The project mobile screenshot 370 may include a plurality of screenshot modification icons 372, a plurality of icons 374, a pair of process buttons 376, and a plurality of screenshot feature icons 378.

The screenshot modification icons 372 may include a send icon 372A, a touchscreen marking icon 372B, an erasing icon 372C, and a closing screenshot icon 372D.

The icons 374 may be the same icons in FIG. 4, 348.

The pair of process buttons 376 may include a Save button 376A to save the project mobile screenshot 370 and a Get Estimate button 376B to send the project mobile screenshot 370 to the system for virtual designing 100 to get an estimate.

The screenshot feature icons 378 may include a plurality of samples 378A. FIG. 9 shows the samples 378A are a plurality of Countertop Faux Wood samples 378AA that include a first dropdown arrow 378B to select a feature such as the Countertop Faux Wood samples 378AA and a second dropdown arrow 378C that may be depressed to show the Select Color 378BB from the Countertop Faux Wood samples 378AA. Additional dropdown arrows 378D may be selected to replace previous dropdown arrows 378E that are highlighted to be changed out.

More specifically, the Countertop Faux Wood samples 378AA may be selected and a user may exit the project mobile screenshot 370 and then select a different Countertop Faux Wood sample 378AA to highlight or perform another function and may present various versions of the highlighted Countertop Faux Wood sample 378AA.

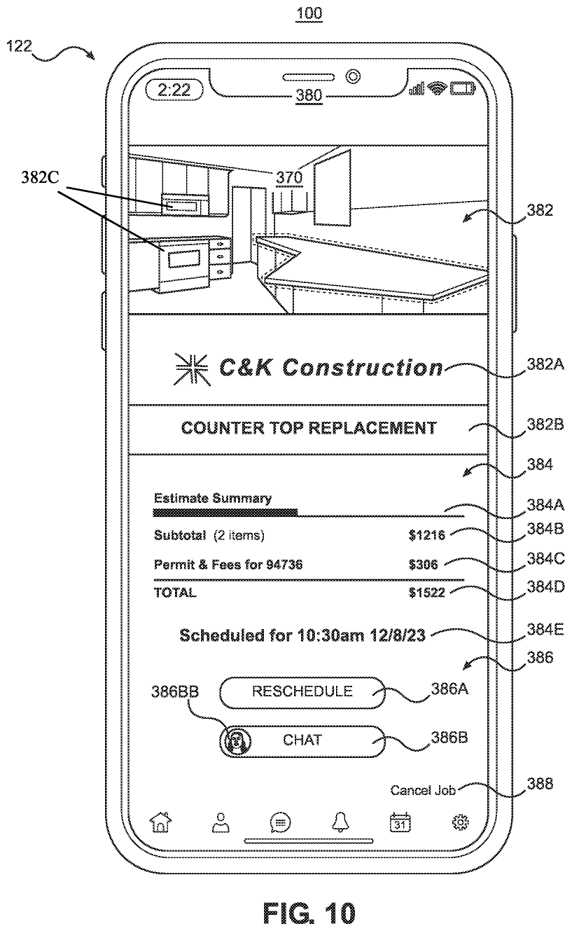

FIG. 10 shows an estimate mobile screenshot 380 of a system for virtual designing 100.

The estimate mobile screenshot 380 may include the project mobile screenshot (FIG. 9, 370), a plurality of contractor information 382, a plurality of project information 384, a pair of buttons 386, and a Cancel Job link 388.

The project mobile screenshot 370 may be the same one in FIG. 9, 370. The contractor information 382 may include a contractor's name 382A and a contractor's type of project 382B. The contractor information 382 may include one or more pieces of furniture 382C to see how the one or more pieces of furniture 382C would look. The project information 384 may include an Estimate Summary Cost 384A, a Subtotal 384B, a Permit & Fees for a Zip Code Cost 384C, a Total Cost 384D, and a Scheduled Appointment Time 384E. The pair of buttons 386 may include a Reschedule Button 386A and a Chat Button 386B with a Chat Operator Photo 386BB. The Cancel Job link 388 may be depressed to cancel a project or the like.

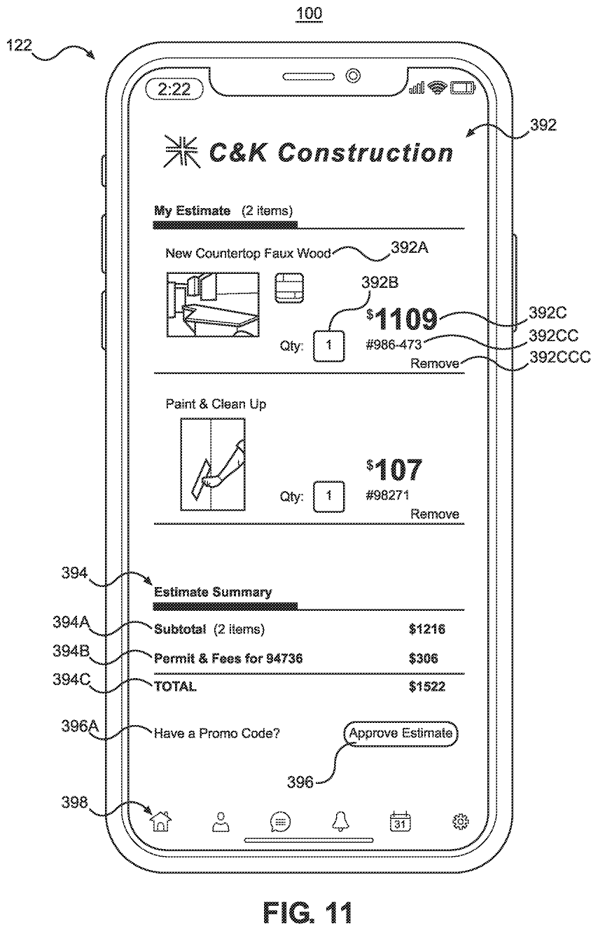

FIG. 11 shows a detailed estimate mobile screenshot 390 of a system for virtual designing 100.

The ailed estimate mobile screenshot 390 may include a plurality of My Estimate Information 392, a plurality of Estimate Summary Information 394, an Approve Estimate button 396, and a plurality of Icons 398.

The My Estimate Information 392 may include a Project Name 392A, a Quantity (Qty:) of each Project 392B, an Estimate Amount 392C with an Order Number 392CC and a Remove Link 392CCC for each project of the estimate 392A.

The Estimate Summary Information 394 may include a Subtotal Cost 394A, a Permit and Fees Cost for a Zip Code 394B, and a Total Cost 394C.

The Approve Estimate button 396 may be depressed to approve the estimate on the detailed estimate mobile screenshot 390 and may also include a “Have a Promo Code?” Link 396A that may be entered to apply the Promo Code entered.

The Icons 398 may be the same as the icons 374 in FIG. 4, 348.

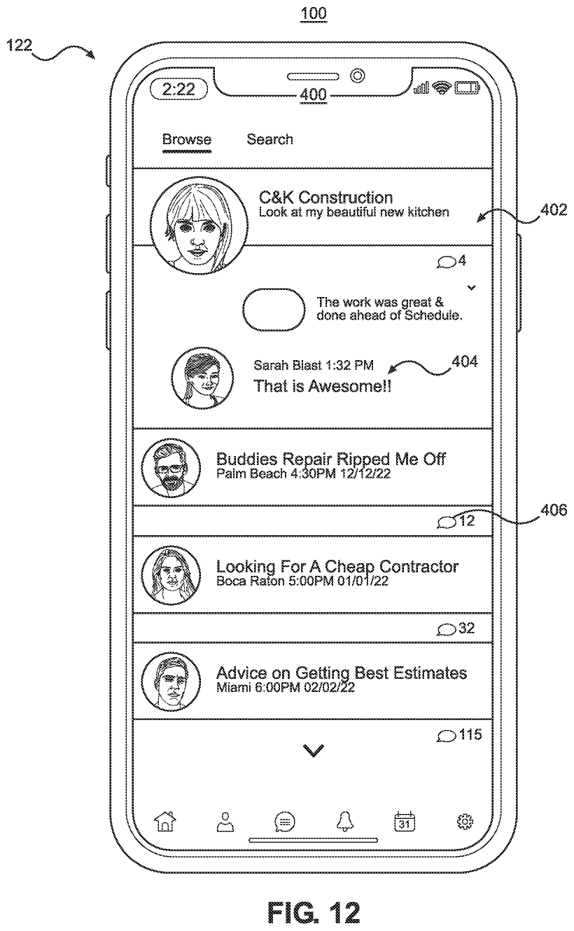

FIG. 12 shows a communications mobile screenshot 400 of a system for virtual designing 100.

The user communications mobile screenshot 400 may include a plurality of online comments 402 that include a plurality of text threads 404. The online comments 402 and the text threads 404 may be from customers and prospective customers and the like.

The user communications mobile screenshot 400 may include a cloud 406 displaying the number of online comments 402 in each of the text threads 404.

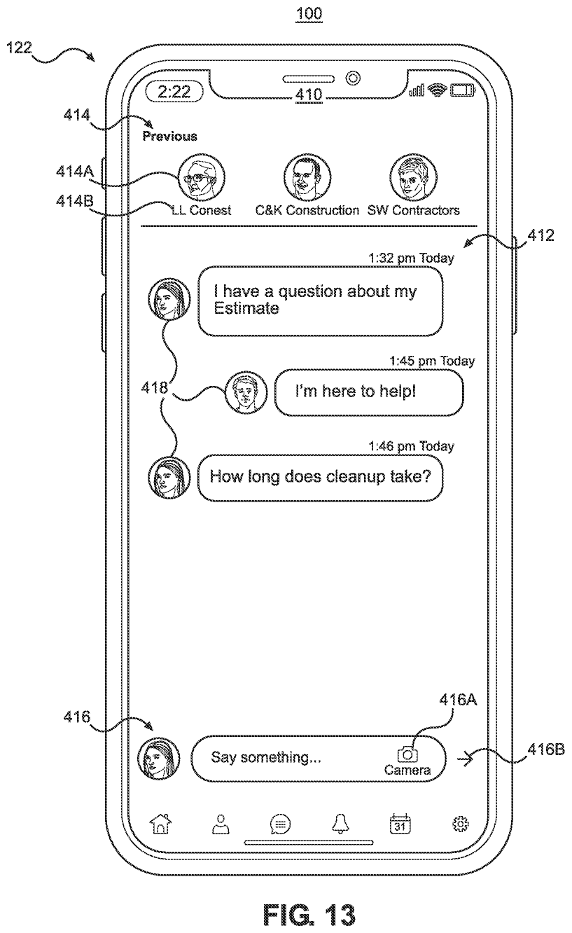

FIG. 13 shows a contractor communications mobile screenshot 410 of a system for virtual designing.

The contractor communications mobile screenshot 410 may include a single text thread 412, one or more previous users 414, a chat box 416, and a plurality of photos 418.

The single text thread 412 may be between at least one customer and at least one contractor. The one or more previous users 414 may include a name 414A and a digital photo 414B. The chat box 416 may be written in and also includes a camera 416A and a sending arrow 416B to send the written text in the chat box 416. The photos 418 may be for a customer and a contractor.

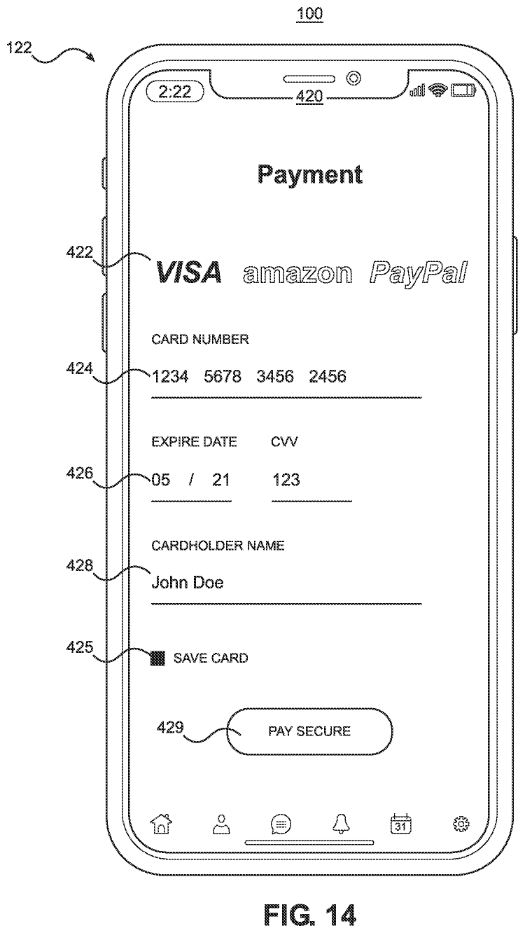

FIG. 14 shows a plurality of payment information mobile screenshot 420 of a system for virtual designing 100.

The payment information mobile screenshot 420 may include a Financial Institution 422, a Card Number 424, an Expiration Date 426, and a Cardholder Name 428.

The Financial Institution 422 may process the payment for the contractor. The Card Number 424 may include any credit card number or debit card number or the like. The Expiration Date 426 may include the month and the year the Card Number 424 expires. The Cardholder Name 428 may include a full name of the cardholder or the like. There is also a Save Card Checkbox 425 to fill to save the payment information mobile screenshot 420 and a Pay Secure button 429 to depress to launch the payment.

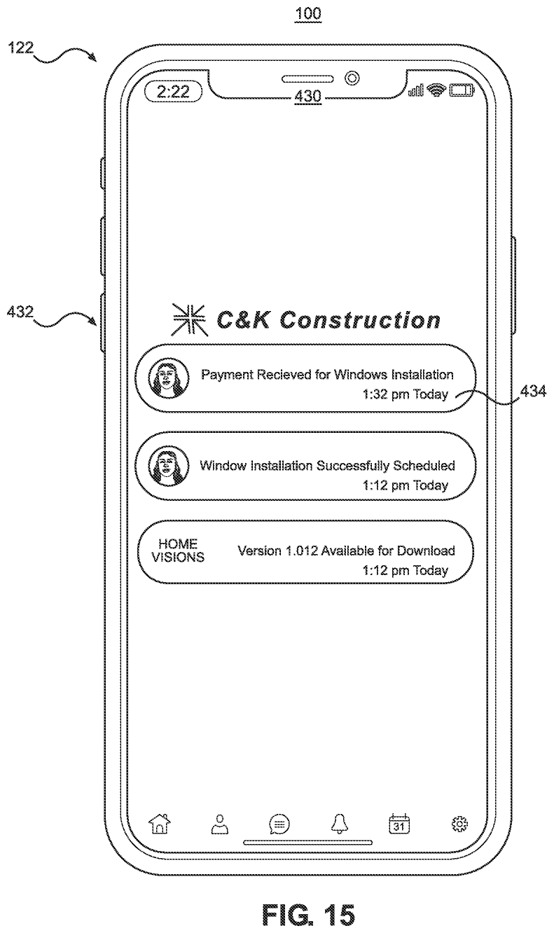

FIG. 15 shows a payment confirmation information mobile screenshot 430 of a system for virtual designing 100.

The payment confirmation information mobile screenshot 430 may include a text message thread 432 confirming a payment for a project. The text message thread 432 may confirm receipt of a payment from a customer. The text message thread 432 may include a timestamp 434 or the like.

It is therefore submitted that the instant invention has been shown and described in various embodiments. It is recognized, however, that departures may be made within the scope of the invention and that obvious modifications will occur to a person skilled in the art. With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

I claim:

1. A system for virtual designing, comprising:
a server system with a processor system, a communications interface, a communications system, an input system and an output system, the server system having access to a communications network;
a memory system with an operating system, a communications module, a web browser module, a web server application, and a non-transitory storage media for virtual designing, the memory system is in communication with the server system through the communications network; and
a plurality of mobile screenshots residing on the non-transitory storage media for virtual designing;
wherein the mobile screenshots are taken with a camera from a client system to record an image of space that saved as one of the mobile screenshots residing on the non-transitory storage media for virtual designing.

2. The system for virtual designing according to claim 1, wherein the image of space is virtually edited with a plurality of colors and designs and includes a plurality of modifiers, a plurality of patterns, a plurality of virtual objects, a plurality of colors, and a plurality of designs that are applied over the image of space.

3. The system for virtual designing according to claim 2, wherein the modifiers, the patterns, the virtual objects, the colors, and the designs are dragged and dropped over the image of space.

4. The system for virtual designing according to claim 1, wherein the mobile screenshots include a cover mobile screenshot, a cover mobile screenshot, an account mobile screenshot, a client information mobile screenshot, a search for contractor mobile screenshot, a plurality of contractor information mobile screenshot, a project mobile screenshot, an estimate mobile screenshot, a detailed estimate mobile screenshot, a communications mobile screenshot, a contractor communications mobile screenshot, a plurality of payment information mobile screenshot, and a payment confirmation information mobile screenshot.

5. The system for virtual designing according to claim 4, wherein the project mobile screenshot is taken by the camera of the client system and serves as the image of space.

6. The system for virtual designing according to claim 5, wherein the project mobile screenshot includes a plurality of screenshot modification icons, a plurality of icons, a pair of process buttons, a plurality of screenshot feature icons, and one or more pieces of furniture to see how the one or more pieces of furniture would look.

7. The system for virtual designing according to claim 6, wherein the screenshot modification icons include a send icon, a touchscreen marking icon, an erasing icon, and a closing screenshot icon.

8. The system for virtual designing according to claim 7, wherein the pair of process buttons include a Save button to save the project mobile screenshot and a Get Estimate button to send the project mobile screenshot to the system for virtual designing to get an estimate.

9. The system for virtual designing according to claim 7, wherein the screenshot feature icons include a plurality of samples.

10. The system for virtual designing according to claim 9, further comprising a Countertop Faux Wood sample is selected and a user exits the project mobile screenshot and then selects a different Countertop Faux Wood sample to highlight or perform another function and present various versions of the highlighted Countertop Faux Wood sample.

11. The system for virtual designing according to claim 5, wherein the estimate mobile screenshot include the project mobile screenshot, a plurality of contractor information, a plurality of project information, a pair of buttons, and a Cancel Job link.

12. The system for virtual designing according to claim 11, wherein the contractor information include a contractor's name and a contractor's type of project.

13. The system for virtual designing according to claim 11, wherein the project information includes an Estimate Summary Cost, a Subtotal, a Permit & Fees for a Zip Code Cost, a Total Cost, and a Scheduled Appointment Time.

14. The system for virtual designing according to claim 11, wherein the pair of buttons include a Reschedule Button and a Chat Button with a Chat Operator Photo.

15. The system for virtual designing according to claim 5, wherein the detailed estimate mobile screenshot includes a plurality of My Estimate Information, a plurality of Estimate Summary Information, an Approve Estimate button, and a plurality of Icons.

16. The system for virtual designing according to claim 15, wherein the My Estimate Information includes a Project Name, a Quantity of each Project, an Estimate Amount with an Order Number and a Remove Link for each project of the estimate.

17. The system for virtual designing according to claim 5, wherein the Estimate Summary Information include a Subtotal Cost, a Permit and Fees Cost for a Zip Code, and a Total Cost.

18. The system for virtual designing according to claim 1, wherein the client system is a Smartphone.

19. A method for virtual designing, comprising the steps of:
obtaining a client system having a camera and a display screen;
taking the camera of the client system to record an image of space;
virtually editing the image of space with a plurality of different colors and a plurality of different designs;
applying over the image of space a plurality of modifiers, a plurality of patterns, a plurality of virtual objects, a plurality of colors, and a plurality of designs; and
dragging and dropping the desired changes over the image of space to visualize a plurality of proposed improvements.

20. A non-transitory computer storage media having instructions stored thereon which, when executed, execute a method for virtual designing comprising the steps of:
obtaining a client system having a camera and a display screen;
taking the camera of the client system to record an image of space;
virtually editing the image of space with a plurality of different colors and a plurality of different designs;
applying over the image of space a plurality of modifiers, a plurality of patterns, a plurality of virtual objects, a plurality of colors, and a plurality of designs; and
dragging and dropping the desired changes over the image of space to visualize a plurality of proposed improvements.
